(19) United States
(12) Patent Application Publication
(10) Pub. No.: US 2025/0199419 A1
(43) Pub. Date: Jun. 19, 2025

(54) METHODS OF METROLOGY AND ASSOCIATED DEVICES

(71) Applicant: ASML NETHERLANDS B.V., Veldhoven (NL)

(72) Inventors: Chrysostomos BATISTAKIS, Eindhoven (NL); Roy WERKMAN, Eindhoven (NL); Maxim PISARENCO, Son en Breugel (NL); Syam Parayil VENUGOPALAN, Eindhoven (NL)

(73) Assignee: ASML NETHERLANDS B.V., Veldhoven (NL)

(21) Appl. No.: 18/847,453

(22) PCT Filed: Mar. 14, 2023
(86) PCT No.: PCT/EP2023/056410

§ 371 Date: Sep. 16, 2024

(30) Foreign Application Priority Data
Apr. 14, 2022 (EP) 22168324.6

(51) Int. Cl. G03F 7/00

(52) U.S. Cl. CPC G03F 7/706841; G03F 7/705; G03F 7/70625

(57) ABSTRACT

A method of inferring second metrology data relating to patterned substrate on which patterns have been exposed and on which processing has been performed, from first metrology data measured on the patterned substrate prior to performance of the processing. The method includes obtaining a model including a first model component. The first model component includes a machine learning model component having been trained to map the first metrology data to the second metrology data, the first model component further including a physics-based input channel for receiving physics-based input data. Second metrology data is inferred from the first metrology data using the first model component as biased by the physics-based input data on the physics-based input channel.

### CROSS-REFERENCE TO RELATED APPLICATION

This application claims priority of EP application Ser. No. 22/168,324.6 which was filed on Apr. 11, 2022 and which is incorporated herein in its entirety by reference.

### FIELD OF THE INVENTION

The present invention relates to methods of metrology performed to maintain performance in the manufacture of devices by patterning processes such as lithography. The invention further relates to methods of manufacturing devices using lithographic techniques. The invention yet further relates to computer program products for use in implementing such methods.

### RELATED ART

A lithographic process is one in which a lithographic apparatus applies a desired pattern onto a substrate, usually onto a target portion of the substrate, after which various processing chemical and/or physical processing steps work through the pattern to create functional features of a complex product. The accurate placement of patterns on the substrate is a chief challenge for reducing the size of circuit components and other products that may be produced by lithography. In particular, the challenge of measuring accurately the features on a substrate which have already been laid down is a critical step in being able to position successive layers of features in superposition accurately enough to produce working devices with a high yield. A particularly important parameter of interest is overlay, which should, in general, be controlled to be within a few tens of nanometers in today's sub-micron semiconductor devices, down to a few nanometers in the most critical layers.

Consequently, modern lithography apparatuses involve extensive measurement or ‘mapping’ operations prior to the step of actually exposing or otherwise patterning the substrate at a target location. However, there is typically only sparse overlay data available due to throughput requirements. Therefore, fitting models (polynomials) and/or other data indicative of overlay (such as alignment data) may be used to derive a dense overlay data map. Such a method is described, for example, in U.S. Pat. No. 10,990,018B2, which is incorporated herein by reference.

It would be desirable to improve inference and/or mapping of a parameter of interest value such as for example overlay, critical dimension (CD) or edge placement error (EPE) as would be measured after a processing step such as etching, to a parameter of interest, based on metrology data measured prior to the processing step.

### SUMMARY OF THE INVENTION

According to a first aspect of the present invention there is provided a method of inferring second metrology data relating to at least one patterned substrate on which patterns have been exposed and on which at least one processing step has been performed, from first metrology data measured on the at least one patterned substrate prior to performance of said at least one processing step; the method comprising: obtaining a model comprising at least one first model component, said at least one first model component comprises a machine learning model component having been trained to map said first metrology data to said second metrology data, said first model component further comprising a physics-based input channel for receiving physics-based input data; and inferring second metrology data from said first metrology data using said first model component as biased by said physics-based input data on said physics-based input channel.

According to a second aspect of the present invention there is provided a computer program product containing one or more sequences of machine-readable instructions for implementing calculating steps in a method according to the first aspect of the invention as set forth above.

The invention yet further provides a processing arrangement and metrology device comprising the computer program of the second aspect.

These and other aspects and advantages of the apparatus and methods disclosed herein will be appreciated from a consideration of the following description and drawings of exemplary embodiments.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus suitable for use in an embodiment of the present invention;

FIG. 2 depicts a lithographic cell or cluster in which an inspection apparatus according to the present invention may be used;

FIG. 3 illustrates schematically measurement and exposure processes in the apparatus of FIG. 1, according to known practice;

FIG. 4 is a flowchart describing a method of obtaining second metrology data from first metrology data and physics-based input data according to an embodiment;

FIGS. 5(a), 5(b) and 5(c) show three zonal configurations for training models according to an embodiment;

FIG. 6 illustrates (a) graphically and (b) schematically a second model component according to an embodiment;

FIG. 7 is a flowchart describing a method of training a hybrid model component, according to an embodiment;

FIG. 8 is a flowchart describing a method of optimizing processing step parameter settings (e.g., etch settings) according to an embodiment; and

FIG. 9 is a flowchart describing a method of optimizing exposure step and/or processing step parameter settings according to an embodiment.

### DETAILED DESCRIPTION OF EXEMPLARY EMBODIMENTS

Before describing embodiments of the invention in detail, it is instructive to present an example environment in which embodiments of the present invention may be implemented.

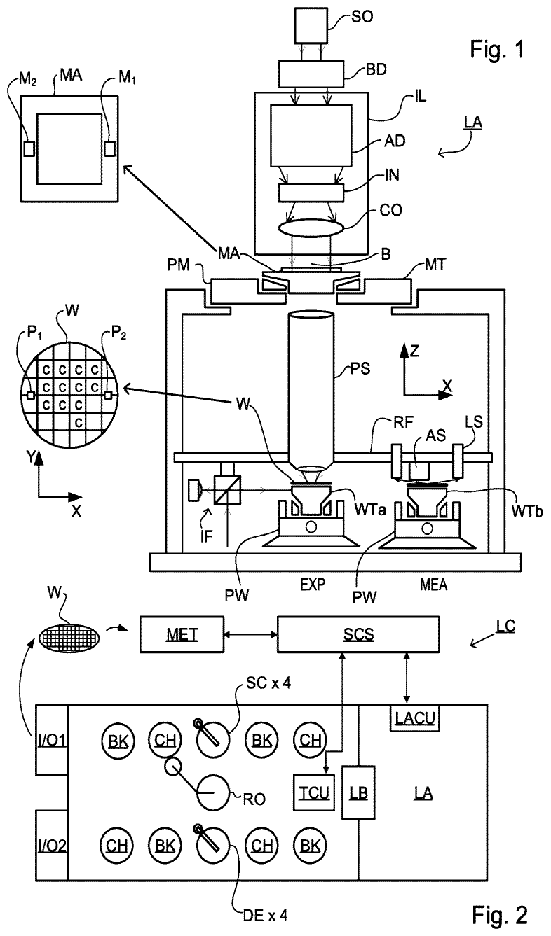

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation. For example, in an apparatus using extreme ultraviolet (EUV) radiation, reflective optical components will normally be used.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers, is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations-an exposure station EXP and a measurement station MEA-between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. On a single stage apparatus, the preparatory steps and exposure steps need to be performed sequentially on the single stage, for each substrate. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

As shown in FIG. 2, the lithographic apparatus LA forms part of a lithographic cell LC, also sometimes referred to a lithocell or cluster, which also includes apparatus to perform pre-and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which lithocell LC is located also includes metrology system MET which receives some or all of the substrates W that have been processed in the lithocell. Metrology results are provided directly or indirectly to the supervisory control system SCS. If errors are detected, adjustments may be made to exposures of subsequent substrates.

Within metrology system MET, an inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it may be desirable that the inspection apparatus measure properties in the exposed resist layer immediately after the exposure. However, not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image-at which point either the exposed or unexposed parts of the resist have been removed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

The metrology step with metrology system MET can also be done after the resist pattern has been etched into a product layer. The latter possibility limits the possibilities for rework of faulty substrates but may provide additional information about the performance of the manufacturing process as a whole.

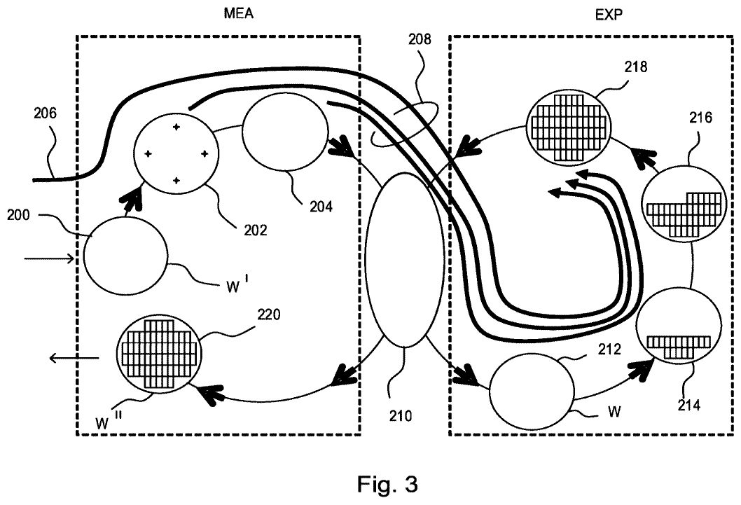

FIG. 3 illustrates the steps to expose target portions (e.g. dies) on a substrate W in the dual stage apparatus of FIG. 1. The process according to conventional practice will be described first. The present disclosure is by no means limited to dual stage apparatus of the illustrated type. The skilled person will recognize that similar operations are performed in other types of lithographic apparatus, for example those having a single substrate stage and a docking metrology stage.

On the left hand side within a dotted box are steps performed at measurement station MEA, while the right hand side shows steps performed at exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. Each patterning step can introduce positional deviations in the applied pattern, while subsequent processing steps progressively introduce distortions in the substrate and/or the pattern applied to it that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation. Some layers may be patterned by steps that are alternative or supplementary to exposure in the illustrated lithographic apparatus. Such alternative and supplementary techniques include for example imprint lithography, self-aligned multiple patterning and directed self-assembly. Similarly, other processing steps performed per layer (e.g., CMP and etch) may be performed on different apparatuses per layer.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a substrate model (sometimes referred to as the “wafer grid”), which maps very accurately the distribution of marks across the substrate, including any distortion relative to a nominal rectangular grid.

At step 204, a map of wafer height (Z) against X-Y position is measured also using the level sensor LS. Primarily, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. Where there is a choice of alignment marks on the substrate, and where there is a choice of settings of an alignment sensor, these choices are defined in an alignment recipe among the recipe data 206. The alignment recipe therefore defines how positions of alignment marks are to be measured, as well as which marks.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

Presently, overlay information is extracted using either direct metrology methods or indirect metrology methods. Direct metrology methods such as decap scanning electron microscope (SEM) metrology and/or high-voltage SEM are too slow for high frequent inline overlay metrology and, in the case of decap metrology, destructive of the device being measured. Indirect metrology methods, such as scatterometry based metrology on optical targets, are typically performed on a set of discrete locations, with a full field and/or full wafer overlay map being constructed by interpolating the measured overlay values at those discrete locations.

In either case, metrology may be performed pre-etch, prior to certain processing steps such as etching and/or polishing (chemical-mechanical polishing CMP), wherein the metrology may be described as after develop inspection (ADI) or after-etch (subsequent to those processing steps), wherein the metrology may be described as after etch inspection (AEI).

It is also known that certain processing effects (e.g., etch and CMP steps) affect parameters of interest such as for example, overlay, critical dimension (CD), edge placement error. Therefore, measurements of the same structures on the same wafer may differ when performed ADI compared to when performed AEI. For example, overlay may be affected by intra-die systematic (IDS) variation, which refers to the systematic variation that is repeated on every die, which originates from such fabrication steps repeated at the die level. As such, various etch parameters and/or contexts (e.g., the actual etch tool and/or chamber used), for example, may affect AEI metrology with respect to ADI metrology. Furthermore, the actual effect of such fabrication processes may also be dependent on the designed layout patterns on the mask, such as local pattern density, target design and/or target location (both within die and on wafer). For example, etching is influenced by the pattern density; the chemistry of the etching plasma above the chip, and therefore the etch rate, selectivity and anisotropy depend on the fraction of photoresist and the fraction of etching waste products generated during the etch process.

For a number of reasons, ADI metrology is often preferred. In one respect, ADI metrology provides a more direct connection between the metrology images obtained during inspection and the various exposure process conditions (e.g., focus, dose, etc.) that define the patterning performance. Inspection of the wafer after development may allow the exposure process conditions to be optimized. Inspection of the wafer after development may allow the wafer to be reworked based on the inspection metrology results. This is not possible after etch; the wafer can no longer be returned to a previous process state for re-processing to improve lithography performance.

However, as etching and/or other processing effect can affect overall lithography or manufacturing performance (e.g., placement performance such as EPE), AEI metrology will be better indicative of overall product performance or yield. As such, it is desirable to be able to predict AEI metrology data from ADI metrology data.

Some models use parameters that are known from etching physics and materials to generate predictive images of the wafer after etching. These models, however, may not generate accurate predictive images because the actual physical parameters of the etching may not be known in practice. Some models tune or calibrate parameters to minimize the difference between physics-based models and predictive images. But these models may not generate accurate predictive images because they do not have enough capacity to represent the complex relationships present in the data.

One method for inferring SEM AEI metrology data from SEM ADI metrology data has been described in WO2021/052918, which is incorporated herein by reference. This describes using a convolutional neural network based machine learning model, and in particular an encoder-decoder based model to map the SEM ADI metrology data to the SEM AEI metrology data (and in particular stochastic metrology data such as defects, line-edge roughness LER, line-width roughness LWR, local critical dimension uniformity LCDU).

The problem with mapping ADI data to AEI data using a purely data-driven model, e.g., using a neural network or other machine learning model without any physics-based input, may be that the mapping is generic and may not allow accurate prediction of the effect of processing variations on AEI metrology data which have not been encountered in training (i.e., the model cannot generalize outside of the training data). Also, while such purely data-driven models have been shown to perform satisfactorily for fixed patterns, they may perform less well when there are significant pattern variations, such as changing pattern densities etc.

Because of these drawbacks, a hybrid modelling method and hybrid model are proposed for inferring second metrology data relating to at least one patterned substrate on which patterns have been exposed and on which at least one processing step has been performed, from first metrology data measured on the at least one patterned substrate prior to performance of said at least one processing step. The method comprises obtaining a model comprising at least one first model component, wherein said (at least one) first model component comprises a machine learning or hybrid data-driven model component having been trained to map said first metrology data to said second metrology data, said first model component further comprising a physics-based input channel for receiving physics-based input data; and inferring second metrology data from said first metrology data using said first model component as biased by said physics-based input data on said physics-based input channel.

As such, the at least one first model component or hybrid data-driven model component may be configured to output different second metrology data (e.g., different output images), given the same first metrology data input (e.g., the same input image), as a result of different physics-based input data (e.g., a different ion tilt parameter value or pattern density value) on said physics-based input channel.

The physics-based input may receive one or more processing step parameters relating to at least one processing step performed on said at least one patterned substrate. The one or more processing step parameters may comprise an etch parameter. In an embodiment, the etch parameter may comprise an ion tilt parameter, e.g., which may have a dependence on substrate (e.g., radial) position. Alternatively or in addition, the physics-based input may receive one or more patterning parameters relating to said patterns, e.g., relating to the field and/or die pattern. An example of a patterning parameter is pattern density.

In this manner, the idea of the hybrid model is to enforce physics-inspired network modifications in order to bias the network output, e.g., to customize a network layer based on a physics-inspired input.

The model may comprise at least one second model component comprising a physics-based model operable to model an effect of said at least one processing step on said second metrology data so as to generate said physics-based input data for the physics-based input channel.

The first metrology data may comprise metrology images. Such metrology images may include one or more of: optical image based overlay results/images (IBO), scatterometry images measured at a pupil plane and/or image plane (e.g., diffraction based overlay (DBO) or in-device metrology (IDM) images measured in a pupil plane/Fourier plane and/or micro-diffraction based overlay (μDBO) images measured in an image plane) and/or scanning electron microscope (SEM)/e-beam images. The second metrology data may also comprise one or more of these image types, or else may comprise values for one or more parameters of interest, or a description of a spatial variation of one or more parameters of interest (e.g. a fitted model or fingerprint of the parameter(s) of interest). The parameter of interest (or fingerprint) output by the model may comprise overlay (or overlay fingerprint) in one or both dimensions of the substrate plane, CD (or a CD fingerprint) or edge placement error (or an EPE fingerprint) for example. Alternatively, the parameter of interest may be one or more stochastic parameters (e.g., provided the first metrology data comprises sufficient information, such as for example SEM images) such as LCDU, LER, LWR, mean CD. As a further alternative, the second metrology data may comprise e-test data (e.g., dense connectivity e-test data).

The first metrology data may comprise measured data, e.g., from an exposed substrate and/or simulated/modeled first metrology data. In the latter case, a first metrology data simulation model (e.g., a neural network or other data-driven model) may be trained and used to generate such simulated/modeled first metrology data based on a scanner settings input (e.g., describing scanner settings or exposure parameters such as focus and/or dose).

The second model may generate said one or more processing step parameters (related to said processing step) and/or patterning parameters (relating to said patterns). Patterning parameters may comprise one or more of: target design parameters such as pitch, cd, design, sub-segmentation parameters, target placement in the die i.e., the coordinate (x,y) of the target and any pattern density data (e.g. pattern density variation surrounding a target or otherwise). Pattern density data may comprise a pattern density spatial distribution or pattern density map. Pattern density maps are low-resolution GDS (graphics design system) files or GDSII files. Due to the large size of GDS files, they are typically downscaled to a low resolution pattern density map in order to be able to process them sufficiently quickly for die-scale applications. A typical resolution of a pattern density map is a 1 μm pixel size.

Note that the term “target” within the context of this disclosure may comprise a metrology target formed for the purposes of metrology and/or any other structure (including functional product structure) being used for metrology (e.g., being measured). As such the patterning parameters may relate to structures other than specific metrology targets, particularly when the first metrology data comprises images obtained using a technology which does not require dedicated targets for measurement (e.g., SEM, some in-device metrology (IDM) methods).

The output of the second model component may comprise data of a similar data type to the output of the model overall (e.g., where a parameter of interest output by the model overall comprises overlay, CD or EPE (or fingerprints thereof), the second model component may relate processing parameters to overlay, CD or EPE (or fingerprints thereof) respectively). Alternatively, the output of the second model component may comprise data of a different data type than the model overall (e.g., the output of the second model component may comprise overlay or CD and the output of the model overall may be EPE or an estimated image or other parameter dependent on the second model component output).

The output of the second model component may comprise values for one or more second model output parameters (e.g., overlay, CD or edge placement error) which may be used directly by the first model component. Optionally, a model or fingerprint may be fitted to these second model output parameter values prior to being input to the first model component. Alternatively the second model component may directly output a second model output fingerprint or second model output spatial variation description.

The processing step may comprise an etch step and the processing step parameter(s) (the physics-based input data) may comprise one or more etch parameters such as, for example, one or more of inter alia: etch pressure, etch flow rate, RF voltage, over-etch, edge ring bias/offset, chamber conditioning, etch tool and/or chamber used. Alternatively or in addition, the process parameter may comprise an ion tilt parameter which may be an effective proxy for some or all of these etch parameters. As already stated, the physics-based input data may also comprise patterning data or pattern density data. AEI overlay and/or CD is highly sensitive to the etch conditions, the target design and its surrounding pattern density variation.

The first model component may comprise a neural network based model and the physics-based input channel (e.g., to which the output of the/each second model component is connected) may be input to an intermediate layer of the neural network, such as the first fully connected layer.

At a basic level, the proposed model may be used to inspect new wafers pre-processed (e.g., pre-etch or ADI) and predict a parameter of interest after processing (e.g., after-etch AEI).

In an embodiment, the proposed model may be used in a method to optimize one or more of the processing parameters so as to improve the parameter of interest post-processing. This may enable parameters which are out-of-specification (spec) when measured ADI to be brought into spec through processing, and/or to improve performance even when originally in spec. How much this is possible may depend on the parameter of interest; for example it is more feasible to bring a parameter such as LCDU or EPE back into spec via etch control, compared to overlay. However, this may change in the future as etcher control improves, for example. In any case, some etch-based AEI overlay control is possible for at least fields closer to the wafer edge by locally changing the direction of the electrical field so as to adjust a tilt of the etching path (ion tilt) which effectively introduces a means of adjusting overlay with a previous layer. Alternatively or in addition, etcher control of the after-etch CD could be used to compensate at least part of the ADI overlay error, for example by slightly increasing the CD of an etched contact layer to ensure there is a sufficient overlap area with previous layers to absorb or compensate for said ADI overlay error.

The model may also be used to make rework decisions. For example, if the model predicts an out-of-spec parameter(s) of interest then it may be decided to perform wafer rework. In an embodiment, the decision may be made only after using the model to determine whether the out-of-spec parameter(s) can be corrected for sufficiently through processing or etch control (e.g., modelling for varied processing parameters and/or contexts); e.g., wafer rework is proposed only when this is deemed not possible.

In an embodiment, the model may be used to determine a scanner-based exposure parameter or parameter-of-interest correction, so as to optimize (or at least bring into spec) the parameter of interest post-processing (e.g., AEI) for the reworked wafer. This means that the model allows a post-processing/AEI parameter of interest to be controlled prior to the new (reworked) exposure. To achieve this, the model may be trained on training metrology data for which the relevant scanner control parameter(s) has/have been varied. Such an embodiment may also include optimizing or bringing into specification a parameter of interest via a co-optimization of scanner and processing tool corrections.

By way of a specific example, training of a model may be based on training metrology data comprising measurements from a focus-exposure or FEM wafer, having had patterns exposed thereon using dose and focus variations near to the best energy and best focus. Such training metrology data may optionally also comprise modelled training metrology data such as that obtained from a model operable to output a metrology image or first metrology data based on various exposure parameter (e.g., focus/dose) inputs. When deciding for wafer rework, instead of adjusting the etch recipe, dose re-targeting or AEI correction (e.g., to improve a stochastic metric such as mean CD or LCDU fingerprints) may be implemented via a dose and/or focus correction.

The physics-based input may enable the impact of processing step parameters and/or patterning parameters on the AEI performance to be assessed. The physics-based input (e.g., comprising a second model output or otherwise) may be connected to one or more layers of the first model, and as such varying the processing tool and/or scanner parameters will modify the model (output) such that the processing specifics (e.g., configuration of etcher/scanner) are taken into account for the AEI prediction.

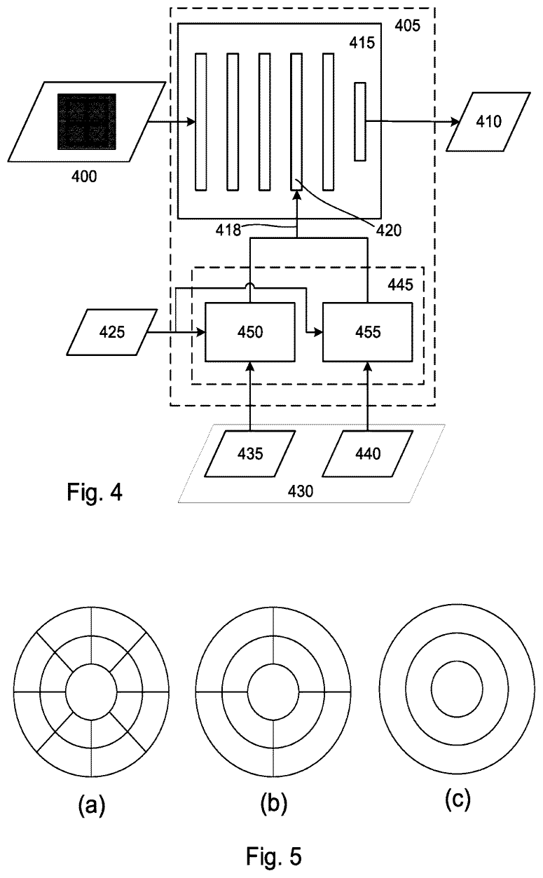

FIG. 4 is a flow diagram describing a method of inferring post-processing (e.g., AEI) parameter of interest data 410 (or post-processing images) from pre-processing (e.g., ADI) data or pre-processing images 400 using a trained hybrid model 405. The pre-processing images may comprise, for example DBO or μDBO images (an example of the latter is illustrated), or SEM/e-beam images for example. The hybrid model comprises a first model component 415 (e.g., a neural network based model component) having a physics-based input channel 418. In an embodiment, at least one second model component (e.g., a physics-based model component) 445 is provided to determine a physics-based input for the physics-based input channel 418. More specifically, in this embodiment, the at least one second model component 445 may comprise one or both of a wafer-scale second model component (e.g., a physical etch chamber model component) 450 and die-scale second model component (e.g., a pattern model component) 455. Processing data 425 (e.g., etch parameter and/or etch context data) may be fed into each of these second model components 450, 455 as well as corresponding layout or patterning data 430 (e.g., wafer-scale location data 435 and die-scale location data 440). The output of the second model components 450, 455 is fed into the physics-based input channel 418 and therefore one or more specific layers 420 (e.g., the first fully connected layer) of the first model component 415.

In an embodiment, across-wafer variation can be handled by dividing the wafer into zones and training a separate model for each zone of the wafer. FIG. 5 shows three purely exemplary embodiments wherein wafer W is divided into (a) 17 zones Z1, (b) 9 zones Z2 and 3 zones Z3. For example, radial etch fingerprints have been noted; this may reduce the number of required zones along the circular direction. The number of zones and their arrangement may therefore differ from that shown. In each case, the respective trained model may be used to infer a parameter of interest from each specific zone. Etch chamber variations can be treated in the same way, i.e., by training a separate model per chamber.

Alternatively, a single model may be conditioned on the wafer zone and/or chamber number. In this case the model is trained with training data from all etch chambers and/or all wafer zones while identifying the chamber and/or zone for respective subsets of the data as an additional input. When using the model for inference, the context information (chamber/zone) is used as an input (e.g., comprised within the physics-based input data) from which the model infers the parameter of interest. A hybrid of these two approaches is also possible (e.g., separate models trained for respective larger zones, the larger zones being sub-divided into smaller sub-zones on which each model may be conditioned.

Where provided, a (e.g., wafer-scale) second module component or physical etch-chamber module component may be used to numerically solve the governing equations, e.g., including the equation of motion of an ion, the equation of conservation of the ion flux and the Poisson equation at plasma reactor scale, to obtain the plasma sheath profile f(Γ, Pᵢ, r) as a function of chamber geometry γ, different physical etch conditions Pᵢ={Pressure, Power, Bias Voltage, Focus ring height . . . } and wafer location (r). The ion tilt at wafer-scale (ion tilt parameter) may then be obtained as φ(r)=∇f(Γ, Pᵢ, r). Determining the ion tilt parameter φ(r) in this manner reduces the parameter space for training the first model component by replacing the multitude of etch-related parameters with a single one-dimensional function of substrate position or substrate radius (i.e., dependent on only the radial distance r from the center of the wafer).

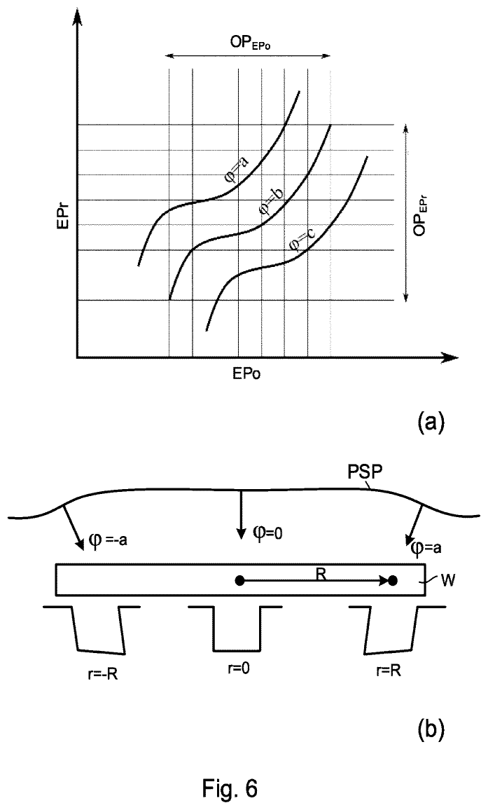

FIG. 6 illustrates this physical etch-chamber module component, FIG. 6(a) is a plot of etch pressure EPr against etch power EPo for three example values of ion tilt parameter φ(φ=a, φ=b, φ=c) within operation ranges OP_{EPr} and OP_{EPo}, illustrating how this ion tilt parameter φ can be used as a proxy for etch power and etch pressure (and other parameters in addition). FIG. 6(b) conceptually illustrates the meaning and effect of the ion tilt parameter φ. The ion tilt parameter φ is related to (e.g., is determined from the normal of) the plasma sheath profile PSP over the substrate W. Three ion tilt parameters are shown φ=−a, φ=0, φ=a. Each of these relate to a specific radial position r on the substrate: r=−R, r=0 and r=R. An example effect of the ion tilt parameter on the etch quality is shown at the bottom of the Figure (e.g., a structure or trench symmetry resultant from the effect of side wall angles and floor tilt). For φ=0 at r=0 (substrate center), the etched structure is symmetrical, while closer to the substrate edge, the etched substrate is asymmetrical due to the effect of non-normal (to the substrate plane) side wall angles and non-parallel (to the substrate plane) floor tilt. This effect is approximately equal in magnitude for all positions at the same radial distance.

In an embodiment, this ion tilt parameter φ may be used (alone or in combination with one or more other parameters) as the physics-based input data for input to the physics-based input channel. In an embodiment, the at least one second model component models this ion tilt parameter φ such that the output of this at least one second model component is fed to the physics-based input channel; e.g., its output is fed into the latent space of the encoder-decoder network of the first model component.

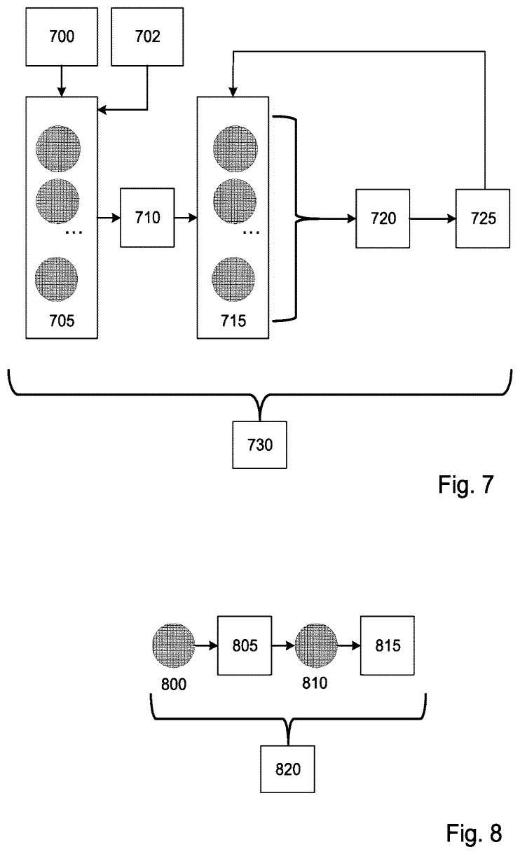

FIG. 7 is a flowchart describing a method for training the first model component. The first model component may be largely data driven, other than being biased by the physics-based input (e.g., a hybrid model component). Step 700 may comprise exposing and measuring one or more training wafers, e.g., to expose fields with various exposure parameter or focus and/or dose values (e.g., expose a focus dose matrix FEM). This step 700 yields training first metrology data 705 (e.g., training first metrology data or pre-processing/ADI training images). Optionally, the training first metrology data 705 may be densified using an additional Neural Network or first metrology data simulation model which has been trained to create 702 artificial ADI data for different dose/focus conditions (e.g., not included in the measured data). The method may further comprise training such a first metrology data simulation model on, for example, training ADI images (e.g., the first metrology data obtained at step 700) and the corresponding known focus/dose settings.

Second metrology data 715 or AEI data may be obtained. For example, in a specific embodiment, the training wafers from which (at least some of) the first metrology data was obtained may be etched 710 with different process step parameter values, e.g., different ion tilt parameter values φ_{1 . . . N}. These etched wafers can then be measured to obtain the second metrology data 715 or AEI data. For example, a respective wafer (or wafer set) comprising a full set of modeled focus/dose parameters is etched using each ion parameter value φ_{1 . . . N} and measured to obtain the second metrology data 715 comprising all combinations of set focus values, set dose values and set ion parameter values (set focus values, set dose values and set ion parameter values may describe a physical setting within a scanner/etcher or an input into a simulation model depending on whether the data is measured or simulated). The training metrology data may also comprise known post-processing or AEI training values; e.g., known values for the AEI parameter(s) of interest (or alternatively output (AEI) training images if the model is trained to output images) which correspond to the ADI training images. This enables a supervised learning of the first model component.

As such, the training data may comprise pre-processing training images and corresponding post-processing training data or images, where corresponding in this context may comprise being measured from the same wafer locations.

At step 730, the first metrology data/ADI data 705 with known exposure parameter values (e.g., known focus/dose values) and the corresponding second metrology data/AEI data 715 is used to train the first model component so that it can map said first metrology data to said second metrology data based on physics-based input data (e.g., the known ion tilt parameter values) on said physics-based input channel. As such, the known values of ion tilt parameter o may be given to the network in an additional channel, e.g., at the last layer of the convolutional part of the model's network and before the model's dense network.

Optionally, at step 720, a second model component or physical etch model may be trained for different values of ion tilt parameter φ. Then, at step 725 new (simulated) AEI data may be generated for additional values of φ (e.g., values not actually etched) to further densify the AEI data 715.

As already been stated, ion tilt parameter φ is only one example of a physics-based input. As such, alternatively or in addition, the AEI data may be generated for variations in another parameter such as another processing step parameter and/or a patterning parameter (e.g., a pattern density parameter). In each case, the known values for the processing step parameter and/or a patterning parameter can be input to the physics-based input channel during training.

As such, the training data may comprise intra-die fingerprints, e.g., obtained by modelling metrology data from different die locations, using a physical die-scale model (e.g., a die-scale second model component), which may be further aware of the surrounding patterns (layout or patterning parameter data). Intra-die and/or intra-target fingerprints predicted by such a die-scale etch model can be used in training the hybrid model for die scale AEI parameter of interest variations.

A similar approach can also be taken to train the first model component for wafer-scale processing (e.g., etch) fingerprints using a separate wafer-scale second model component (e.g., the model may comprise more than one second model component). Moreover, data taken from different processing tools or etch chambers can also be used to train the first model component for the tool/chamber fingerprints.

FIG. 8 is a flow diagram illustrating a first example application of the hybrid model described herein. At step 800, an exposed wafer is inspected ADI to obtain ADI image data (first metrology data). At step 805, the ADI image data is input to the first model component, along with an ion tilt parameter φ and/or other physics-based input data on the physics-based input channel; based on this the first model component predicts an AEI image or AEI image data (second metrology data) 810. The ion tilt parameter φ and/or other physics-based input data may be known or may be provided by one or more second model components such as have been described. At step 815 the predicted AEI image data is assessed, e.g., compared to a desired equivalent value or range across the wafer. At step 820, steps 805 to 815 may be repeated for different values physical parameter values (e.g., for different ion tilt parameter φ values) until an optimal, or at least acceptable, physical parameter value is found.

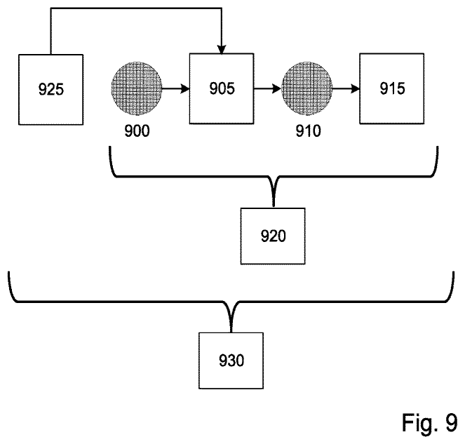

FIG. 9 is a flow diagram illustrating a first example application of the hybrid model described herein. Steps 900 to 920 correspond to steps 800 to 820 and will not be described again, other than the first model component now receives (e.g., at step 905) simulated ADI data 925 generated for different exposure parameters (e.g., focus/dose conditions), e.g., using a first metrology data simulation model. An additional optimization is performed at step 930, which repeats the other steps 905-925 with varied exposure parameters till an optimal (or at least acceptable) AEI result is predicted. Based on the prediction, scanner rework exposure settings may be determined, and/or an alert raised if no acceptable performance can be found.

The proposed methods can be used in combination with reinforcement learning methods, thereby improving the generalization power of the reinforcement learning approach. For instance, where a reinforcement learning approach is used in high volume manufacturing (HVM), it might not learn much when the etch process is stable due to the lack of variability in the data. The present approach on the other hand, will learn all the necessary information during minimal training (since it is physically inspired) and be used to improve performance in HVM using reinforcement learning.

This hybrid model approach enables optimal configuration of the relevant post-ADI processing (etching) such that the expected AEI performance (based on ADI input) is improved. Alternatively wafers for which ADI performance indicates AEI performance will never meet requirements may be sent for re-work; optionally the model may also optimize scanner settings/corrections (or co-optimize scanner and etcher settings/corrections) for the re-working so as to improve AEI performance.

In association with the hardware of the lithographic apparatus and the lithocell LC, an embodiment may include a computer program containing one or more sequences of machine-readable instructions for causing the processors of the lithographic manufacturing system to implement methods of model mapping and control as described above. This computer program may be executed for example in a separate computer system employed for the image calculation/control process. Alternatively, the calculation steps may be wholly or partly performed within a processor a metrology tool, and/or the control unit LACU and/or supervisory control system SCS of FIGS. 1 and 2. There may also be provided a data storage medium (e.g., semiconductor memory, magnetic or optical disk) having such a computer program stored therein in non-transient form.

Although specific reference may have been made above to the use of embodiments of the invention in the context of optical lithography, it will be appreciated that the invention may be used in other patterning applications, for example imprint lithography. In imprint lithography, topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further embodiments are disclosed in the subsequent list of numbered clauses:
1. A method of inferring second metrology data relating to at least one patterned substrate on which patterns have been exposed and on which at least one processing step has been performed, from first metrology data measured on the at least one patterned substrate prior to performance of said at least one processing step; the method comprising:
   obtaining a model comprising at least one first model component and at least one second model component, wherein said at least one first model component comprises a machine learning model component having been trained to map said first metrology data to said second metrology data and said at least one second model component comprises a physics-based model operable to model an effect of said at least one processing step on said second metrology data; and
   inferring second metrology data from said first metrology data using said first model component;
   wherein an output of said at least one second model component is used by said first model component in said inferring said second metrology data.
2. A method as described in clause 1, wherein the first metrology data comprises metrology images or representations thereof.
3. A method as described in clause 2, wherein said metrology images may include one or more of: image based overlay images, scatterometry images captured at a Fourier plane, scatterometry images captured at an image plane or scanning electron microscope images. [comment]
4. A method as described in any preceding clause, wherein said second metrology data comprises values for one or more parameters of interest or a description of a spatial variation of one or more parameters of interest.
5. A method as described in clause 4, wherein said parameter of interest comprises one or more of: overlay, CD, edge placement error, line-edge roughness, line-width roughness, local critical dimension uniformity, mean critical dimension.
6. A method as described in any of clauses 1 to 3, wherein said second metrology data comprises e-test data.
7. A method as described in any of clauses 1 to 3, wherein the second metrology data comprises metrology images or representations thereof.
8. A method as described in any preceding clause, wherein the at least one second model relates the effect on said second metrology data, of one or more processing step parameters related to said processing step and/or patterning parameters relating to said patterns.
9. A method as described in clause 8, wherein said patterning parameters comprise at least target design parameters.
10. A method as described in clause 9, wherein said target design parameters comprise one or more of: target pitch(es), critical dimension, target design, target sub-segmentation parameters, target placement in the die, target location, any parameters of surrounding and/or neighboring structures which surround and/or neighbor said target.
11. A method as described in clause 8, 9 or 10, wherein said patterning parameters comprise one or more pattern density parameters relating to any of said patterns.
12. A method as described in any preceding clause, wherein said output of the second model component comprises values for one or more second model output parameters.
13. A method as described in clause 12, wherein, in said inferring step, the first model component directly uses said values for one or more second model output parameters.
14. A method as described in clause 13, comprising a step of fitting a model to said values for one or more second model output parameters; wherein said fitted model is used by said first model component in said inferring said second metrology data.
15. A method as described in any preceding clause, wherein said processing step comprises at least an etch step; and the process parameters comprise one or more etch parameters.
16. A method as described in clause 15, wherein said etch parameters comprise one or more of: etch pressure, etch flow rate, RF voltage, over-etch, edge ring bias/offset, chamber conditioning, the etch tool and/or chamber used.
17. A method as described in any preceding clause, wherein said at least one first model component comprises a neural network based model.
18. A method as described in clause 17, wherein the output of the second model component is input to an intermediate layer of the neural network.
19. A method as described in clause 18, wherein the output of the second model component is input to the first fully connected layer of the neural network.
20. A method as described in any preceding clause, comprising determining a setting and/or correction for one or more processing parameters relating to said processing step so as to optimize and/or bring into specification said second metrology data.
21. A method as described in clause 20, comprising a step of performing said processing step based on the determined setting and/or correction.
22. A method as described in any preceding clause, comprising determining whether said patterned substrate should be reworked based on said second metrology data.
23. A method as described in clause 22, comprising deciding that a wafer should be reworked only after using the model to determine that the second metrology data inferred by the model cannot be sufficiently corrected via said processing step.
24. A method as described in clause 22 or 23, comprising using said model to determine a setting and/or correction for one or more exposure parameters for exposure of patterns on the reworked substrate so as to optimize and/or bring into specification said second metrology data.
25. A method as described in clause 22 or 23, comprising using said model to co-optimize a setting and/or correction for one or more exposure parameters for exposure of patterns on the reworked substrate and to determining a setting and/or correction for one or more processing parameters relating to said processing step so as to optimize and/or bring into specification said second metrology data.
26. A method as described in clause 24 or 25, comprising performing said rework based on said setting and/or correction for one or more exposure parameters.
27. A method as described in any preceding clause, comprising performing an initial training step to train said model, the training step comprising:
   training said at least one first model component on training metrology data and corresponding second model component output training data or equivalent measured data, wherein the training metrology data comprises known data similar to said first metrology data and said second metrology data.
28. A method as described in clause 27, wherein said second model component output training data or equivalent measured data comprises one or more of: spatial descriptions or values of one or more parameters of interest, wherein the spatial descriptions or values are described intra-die, intra-target, across-wafer or per processing tool/chamber.
29. A method as described in clause 27 or 28, comprising training the model on training data related to variation of one or more exposure tool parameters and/or processing tool parameters.
30. A method as described in any of clauses 27 to 29, comprising training separate instances of said model, to obtain a respective trained model for each of two or more substrate zones and/or two or more processing tools or chambers; and
   said inferring step comprises using the corresponding trained model for its respective substrate zone and/or processing tool or chamber.
31. A method as described in any of clauses 27 to 29, wherein the training comprises conditioning a single model for the whole substrate and/or all processing tools and chambers, by including to which wafer zone and/or chamber number said training data relates within the training data.
32. A method as described in any preceding clause, wherein the at least one second model component comprises one or more of a die-scale second model component and a wafer scale second model component.
33. A computer program comprising program instructions operable to perform the method of any preceding clause, when run on a suitable apparatus.
34. A non-transient computer program carrier comprising the computer program of clause 33.
35. A processing arrangement comprising:
   a computer program carrier comprising the computer program of clause 33; and
   a processor operable to run said computer program.
36. A metrology device comprising the processing arrangement of clause 35.
37. A method of inferring second metrology data relating to at least one patterned substrate on which patterns have been exposed and on which at least one processing step has been performed, from first metrology data measured on the at least one patterned substrate prior to performance of said at least one processing step; the method comprising: obtaining a model comprising at least one first model component, said at least one first model component comprises a machine learning model component having been trained to map said first metrology data to said second metrology data, said first model component further comprising a physics-based input channel for receiving physics-based input data; and inferring second metrology data from said first metrology data using said first model component as biased by said physics-based input data on said physics-based input channel.
38. A method according to clause 37, wherein the first metrology data comprises metrology images or representations thereof.
39. A method according to clause 38, wherein said metrology images may include one or more of: image based overlay images, scatterometry images captured at a Fourier plane, scatterometry images captured at an image plane or scanning electron microscope images.
40. A method according to any of clauses 37 to 39, wherein said second metrology data comprises values for one or more parameters of interest or a description of a spatial variation of one or more parameters of interest.
41. A method according to clause 40, wherein said parameter of interest comprises overlay, CD or edge placement error, in each case in one or both dimensions of the substrate plane.
42. A method according to clause 40, wherein said parameter of interest comprises one or more of line-edge roughness, line-width roughness, local critical dimension uniformity, mean critical dimension.
43. A method according to any of clauses 37 to 39, wherein said second metrology data comprises e-test data.
44. A method according to any of clauses 37 to 39, wherein the second metrology data comprises metrology images or representations thereof.
45. A method according to any of clauses 37 to 44, wherein said physics-based input data comprises one or more processing step parameters related to said processing step and/or one or more patterning parameters relating to said patterns.
46. A method according to clause 45, wherein said patterning parameters comprise at least target design parameters.
47. A method according to clause 46, wherein said target design parameters comprise one or more of: target pitch(es), critical dimension, target design, target sub-segmentation parameters, target placement in the die, target location, any parameters of surrounding and/or neighboring structures which surround and/or neighbor said target.
48. A method according to clause 45, 46 or 47, wherein said patterning parameters comprise one or more pattern density parameters relating to any of said patterns.
49. A method according to any of clauses 45 to 48, wherein said processing step comprises at least an etch step; and the one or more processing step parameters comprise one or more etch parameters.
50. A method according to clause 49, wherein said etch parameters comprise one or more of: etch pressure, etch flow rate, RF voltage, over-etch, edge ring bias/offset, chamber conditioning, the etch tool and/or chamber used.
51. A method according to clause 49 or 50, wherein said one or more etch parameters comprises an ion tilt parameter.
52. A method according to clause 51, wherein said ion tilt parameter is dependent only on radial position on the substrate.
53. A method according to any of clauses 37 to 52, wherein, in said inferring step, the first model component directly uses said physics-based input data.
54. A method according to any of clauses 37 to 52, comprising a step of fitting a model to said physics-based input data; wherein said fitted model is used by said first model component in said inferring said second metrology data.
55. A method according to any of clauses 37 to 54, wherein said model comprises at least one second model component, each said at least one second model component comprising a respective physics-based model operable to generate said physics-based input data for the physics-based input channel.
56. A method according to clause 55, wherein the at least one second model component comprises one or more of: a die-scale second model component and/or a wafer scale second model component.
57. A method according to clause 55 or 56, wherein the at least one second model component comprises a physical etch chamber model component.
58. A method according to clause 55, 56 or 57, wherein the at least one second model component comprises a pattern model component.
59. A method according to any of clauses 37 to 58, wherein said at least one first model component comprises a neural network based model.
60. A method according to clause 59, wherein the physics-based input data is input to an intermediate layer of the neural network.
61. A method according to clause 59 or 60, wherein the physics-based input data is input to the first fully connected layer of the neural network.
62. A method according to any of clauses 37 to 61, comprising determining a setting and/or correction for one or more processing step parameters relating to said processing step so as to optimize and/or bring into specification said second metrology data.
63. A method according to clause 62, comprising a step of performing said processing step based on the determined setting and/or correction.
64. A method according to any of clauses 37 to 63, comprising determining whether said patterned substrate should be reworked based on said second metrology data.
65. A method according to clause 64, comprising deciding that a wafer should be reworked only after using the model to determine that the second metrology data inferred by the model cannot be sufficiently corrected via said processing step.
66. A method according to clause 64 or 65, comprising using said model to determine a setting and/or correction for one or more exposure parameters for exposure of patterns on the reworked substrate so as to optimize and/or bring into specification said second metrology data.
67. A method according to clause 64 or 65, comprising using said model to co-optimize a setting and/or correction for one or more exposure parameters for exposure of patterns on the reworked substrate and to determining a setting and/or correction for one or more processing step parameters relating to said processing step so as to optimize and/or bring into specification said second metrology data.
68. A method according to clause 66 or 67, comprising performing said rework based on said setting and/or correction for one or more exposure parameters.
69. A method according to any of clauses 37 to 68, comprising performing an initial training step to train said model, the training step comprising: training said at least one first model component on training metrology data and corresponding training physics-based input data, wherein the training metrology data comprises known data similar to said first metrology data and said second metrology data.
70. A method according to clause 69, wherein said training physics-based input data comprises one or more of: spatial descriptions or values of one or more parameters of interest, wherein the spatial descriptions or values are described intra-field, intra-die, intra-target, across-wafer or per processing tool/chamber.
71. A method according to clause 69 or 70, wherein said training physics-based input data comprises one or more patterning parameters relating to said patterns and/or data relating to one or more etch parameters.
72. A method according to clause 71, wherein said etch parameters comprise one or more of: etch pressure, etch flow rate, RF voltage, over-etch, edge ring bias/offset, chamber conditioning, the etch tool and/or chamber used.
73. A method according to clause 71 or 72, wherein said one or more etch parameters comprises an ion tilt parameter.
74. A method according to any of clauses 69 to 73, comprising training the model on training data related to variation of one or more exposure tool parameters and/or processing tool parameters.
75. A method according to any of clauses 69 to 74, comprising training separate instances of said model, to obtain a respective trained model for each of two or more substrate zones and/or two or more processing tools or chambers; and said inferring step comprises using the corresponding trained model for its respective substrate zone and/or processing tool or chamber.
76. A method according to any of clauses 69 to 74, wherein the training comprises conditioning a single model for the whole substrate and/or all processing tools and chambers, by including to which wafer zone and/or chamber number said training data relates within the training data.
77. A computer program comprising program instructions operable to perform the method of any of clauses 37 to 76, when run on a suitable apparatus.
78. A non-transient computer program carrier comprising the computer program of clause 77.
79. A processing arrangement comprising:
   a computer program carrier comprising the computer program of clause 77; and
   a processor operable to run said computer program.
80. A metrology device comprising the processing arrangement of clause 79.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A method of inferring second metrology data relating to at least one patterned substrate on which patterns have been exposed and on which at least one processing step has been performed, from first metrology data measured on the at least one patterned substrate prior to performance of the at least one processing step, the method comprising:
obtaining a model comprising at least one first model component, the at least one first model component comprising a machine learning model component having been trained to map the first metrology data to the second metrology data, the at least one first model component further comprising a physics-based input channel for receiving physics-based input data; and
inferring second metrology data from the first metrology data using the at least one first model component as biased by the physics-based input data on the physics-based input channel.

2. The method as claimed in claim 1, wherein the first metrology data comprises one or more metrology images or representations thereof.

3. The method as claimed in claim 2, wherein the one or more metrology images may include one or more selected from: one or more image based overlay images, one or more scatterometry images captured at a Fourier plane, one or more scatterometry images captured at an image plane, or one or more scanning electron microscope images.

4. The method as claimed in claim 1, wherein the second metrology data comprises values for one or more parameters of interest or a description of a spatial variation of one or more parameters of interest.

5. The method as claimed in claim 4, wherein the one or more parameters of interest comprise overlay, critical dimension (CD) or edge placement error (EPE).

6. The method as claimed in claim 4, wherein the one or more parameters of interest comprise one or more selected from: line-edge roughness, line-width roughness, local critical dimension uniformity, or mean critical dimension.

7. The method as claimed in claim 1, wherein the second metrology data comprises e-test data.

8. The method as claimed in claim 1, wherein the second metrology data comprises metrology images or representations thereof.

9. The method as claimed in claim 1, wherein the physics-based input data comprises one or more processing step parameters related to the at least one processing step and/or one or more patterning parameters relating to the patterns.

10. The method as claimed in claim 9, wherein the physics-based input data comprises the one or more patterning parameters relating to the patterns and the one or more patterning parameters comprise at least one target design parameter.

11. The method as claimed in claim 10, wherein the at least one target design parameter comprises one or more selected from: target pitch(es), target critical dimension, target design, a target sub-segmentation parameter, target placement in the die, target location, or any parameter of surrounding and/or neighboring structures which surround and/or neighbor the target.

12. The method as claimed in claim 9, wherein the physics-based input data comprises the one or more patterning parameters relating to the patterns and the one or more patterning parameters comprise one or more pattern density parameters relating to any of the patterns.

13. The method as claimed in claim 9, wherein the at least one processing step comprises at least an etch step; and wherein the physics-based input data comprises the one or more processing step parameters related to the at least one processing step and the one or more processing step parameters comprise one or more etch parameters.

14. The method as claimed in claim 1, wherein the model comprises at least one second model component, each at least one second model component comprising a respective physics-based model operable to generate the physics-based input data for the physics-based input channel.

15. A non-transitory computer program product comprising program instructions configured operable to perform at least the method of claim 1, when run on a suitable apparatus.

16. A method of inferring second metrology data relating to at least one patterned substrate on which patterns have been exposed and on which at least one processing step has been performed, from first metrology data measured on the at least one patterned substrate prior to performance of the at least one processing step; the method comprising:
obtaining a model comprising at least one first model component and at least one second model component, wherein the at least one first model component comprises a machine learning model component having been trained to map the first metrology data to the second metrology data and the at least one second model component comprises a physics-based model operable to model an effect of the at least one processing step on the second metrology data; and
inferring second metrology data from the first metrology data using the first model component,
wherein an output of the at least one second model component is used by the first model component in the inferring the second metrology data.

17. The method as claimed in claim 16, wherein the first metrology data comprises metrology images or representations thereof.

18. The method as claimed in claim 16, wherein the second metrology data comprises values for one or more parameters of interest or a description of a spatial variation of one or more parameters of interest.

19. The method as claimed in claim 16, wherein the second metrology data comprises e-test data or comprises metrology images or representations thereof.

20. A non-transitory computer program product comprising program instructions configured to perform at least the method of claim 16, when run on a suitable apparatus.
